(19) United States
(12) Patent Application Publication
(10) Pub. No.: US 2026/0105872 A1
(43) Pub. Date: Apr. 16, 2026

(54) SYSTEM AND METHOD THEREOF FOR DISPLAYING MULTIMEDIA CONTENT ON AT LEAST ONE COMPUTER COOLING FAN

(71) Applicant: Yossi Rubin, Kiryat Motzkin (IL)

(72) Inventor: Yossi RUBIN, Kiryat Motzkin (IL)

(73) Assignee: Yossi Rubin, Kiryat Motzkin (IL)

(21) Appl. No.: 19/356,650

(22) Filed: Oct. 13, 2025

Related U.S. Application Data
(60) Provisional application No. 63/707,013, filed on Oct. 14, 2024.

(51) Int. Cl. G09G 3/00; F04D 29/52; G06F 1/20; H05K 7/20

(52) U.S. Cl. CPC G09G 3/001; F04D 29/522; G06F 1/20; H05K 7/20136

(57) ABSTRACT

A system for displaying multimedia content on a computer cooling fan, comprising: a frame having a central cavity; a fan within the cavity, wherein the fan includes a hub and fan blades, each fan blade having a back surface and a front surface opposite thereto, wherein each fan blade has a first end attached to the hub and a second end opposite thereto, the cavity receives the fan such that the hub and fan blades rotate together therein; a display strip mounted to a point on a surface of one of the fan blades, the display strip arranged to rotate as the fan rotates when it rotates; and circuitry regulating what is displayed by the display strip over time so that a multimedia content is perceived to be displayed by an observer of the system regardless of an instantaneous rotation speed of the fan.

### CROSS REFERENCE TO RELATED APPLICATIONS

This application claims the benefit of U.S. Provisional Application No. 63/707,013 filed on Oct. 14, 2024, the contents of which are incorporated herein by reference.

### TECHNICAL FIELD

The present disclosure generally relates to computer fans and more specifically, it pertains to a system and method thereof for displaying multimedia content on at least one computer cooling fan.

### BACKGROUND

Over the years, cooling fans have become essential components in consumer electronic devices, particularly personal computers (PCs), to maintain optimal temperatures and prevent overheating. Many current cooling fans are designed with decorative features, such as single-color or red-green-blue (RGB) light emitting diodes (LEDs), positioned around or adjacent to the fan frame, which illuminate the fan hub to create a visual effect.

These lighting solutions, while aesthetically pleasing, have primarily been limited to basic illumination, offering little room for user customization beyond simple light patterns.

As the PC market has evolved, so too has the demand for personalized and creative computing experiences. While laptops dominate general office use, desktop PCs are increasingly owned by gamers, hobbyists, and custom builders who seek to differentiate their systems through unique visual modifications. This has driven a trend toward artistic expression in PC design, with users competing to add flair and distinction to their builds.

Despite these demands, current fan lighting solutions remain constrained in their capabilities. Single-color LED implementations typically offer no opportunity for color blending or dynamic visual effects. RGB LED systems, though offering multi-color options, are often restricted to simple pre-programmed variations and therefore limited to light-based decoration.

It would therefore be advantageous to provide a solution that overcomes the challenges noted above.

### SUMMARY OF THE DISCLOSURE

A summary of several example embodiments of the disclosure follows. This summary is provided for the convenience of the reader to provide a basic understanding of such embodiments and does not wholly define the breadth of the disclosure. This summary is not an extensive overview of all contemplated embodiments and is intended to neither identify key or critical elements of all embodiments nor to delineate the scope of any or all aspects. Its sole purpose is to present some concepts of one or more embodiments in a simplified form as a prelude to the more detailed description that is presented later. For convenience, the term “certain embodiments” may be used herein to refer to a single embodiment or multiple embodiments of the disclosure.

Certain embodiments disclosed herein include a system for displaying multimedia content on a computer cooling fan. The system comprises: a frame having a central cavity; a computer cooling fan positioned within the central cavity, wherein the computer cooling fan includes at least a hub and a plurality of fan blades, wherein each fan blade of the plurality of fan blades has a back surface directed to the central cavity and a front surface being opposite to the back surface, wherein each fan blade of the plurality of fan blades has a first end that is attached to the hub and a second end being opposite to the first end, wherein the central cavity is adapted to receive the computer cooling fan such that the hub and the plurality of fan blades are adapted to rotate together within the central cavity; at least one display strip mounted to at least one point of one of the front surface and the back surface of at least one of the plurality of fan blades, wherein the at least one display strip is arranged so as to rotate within the central cavity at the same rate as computer cooling fan rotates when the computer cooling fan is rotating; and circuitry regulating what is displayed by the at least one display strip over time so that a multimedia content is perceived to be displayed by an observer of the system regardless of an instantaneous rotation speed of the computer cooling fan.

Certain embodiments disclosed herein include a method for displaying multimedia content on a computer cooling fan, the computer cooling fan comprising: a frame having a central cavity; a computer cooling fan positioned within the central cavity, wherein the computer cooling fan includes at least a hub and a plurality of fan blades, wherein each fan blade of the plurality of fan blades has a back surface directed to the central cavity and a front surface being opposite to the back surface, wherein each fan blade of the plurality of fan blades has a first end that is attached to the hub and a second end being opposite to the first end, wherein the central cavity is adapted to receive the computer cooling fan such that the hub and the plurality of fan blades are adapted to rotate together within the central cavity; at least one display strip mounted to at least one point of one of the front surface and the back surface of at least one of the plurality of fan blades, wherein the at least one display strip is arranged so as to rotate within the central cavity at the same rate as computer cooling fan rotates when the computer cooling fan is rotating; and circuitry regulating what is displayed by the at least one display strip over time so that a multimedia content is perceived to be displayed by an observer of the computer cooling fan regardless of an instantaneous rotation speed of the computer cooling fan. The method comprises: receiving the multimedia content; obtaining real-time processing data; generating a display strips' operation schedule for controlling the at least one display strip so as to display of the multimedia content; and supplying the display strips' operation schedule to at least one display controller configured to operate each display element of the at least one display strip based on the display strips' operation schedule.

### BRIEF DESCRIPTION OF THE DRAWING

In the drawing:

FIG. 1 shows an assembled view of an illustrative system for displaying multimedia content on a computer cooling fan, according to an embodiment;

FIG. 2 shows a disassembled view of the components of the illustrative system of FIG. 1;

FIG. 3 which shows an illustrative structure for a display management module and a display controller, according to an embodiment

FIG. 4 which shows an isometric view of a system 400, according to an embodiment

FIG. 4 is an isometric view of an illustrative system for displaying multimedia content on a computer cooling fan having a single display strip, according to an embodiment;

FIG. 5 is another isometric view of another illustrative system for displaying multimedia content on a computer cooling fan, according to an embodiment;

FIGs. 6A-6B each shows a front view of an illustrative system for displaying multimedia content on a computer cooling fan with multimedia content is displayed, according to an embodiment; and

FIG. 7 shows a flowchart of an illustrative method for displaying multimedia content on a computer cooling fan, according to an embodiment.

### DETAILED DESCRIPTION

It is important to note that the embodiments disclosed herein are only examples of the many advantageous uses of the innovative teachings herein. In general, statements made in the specification of the present application do not necessarily limit any of the various claimed embodiments. Moreover, some statements may apply to some inventive features but not to others. In general, unless otherwise indicated, singular elements may be in plural and vice versa with no loss of generality. In the drawings, like numerals refer to like parts through several views.

A system and methods thereof for displaying multimedia content on a computer cooling fan is disclosed. The system includes a frame having a central cavity; a computer cooling fan positioned within the central cavity. The computer cooling fan includes a hub and fan blades. Each fan blade has a back surface directed generally toward the central cavity and a front surface being opposite to the back surface. Each fan blade has a first end that is attached to the hub and a second end that is opposite to the first end. Note that the second end of the fan blade is that portion of the fan blade that is distal from the hub and may be located in proximity to the portion of the frame that defines the central cavity. The central cavity is adapted to receive the computer cooling fan such that the fan blades are adapted to rotate within the central cavity. In one embodiment, at least one display strip is mounted to the front surface and/or the back surface of at least one fan blade, e.g., adjacent to a portion of the second end of a fan blade. In another embodiment, the display strip is placed so that it extends from the center of the hub toward a point on the second end of the fan blade which may be at or adjacent to the second end, e.g., on the front surface and/or the back surface of the fan blade.

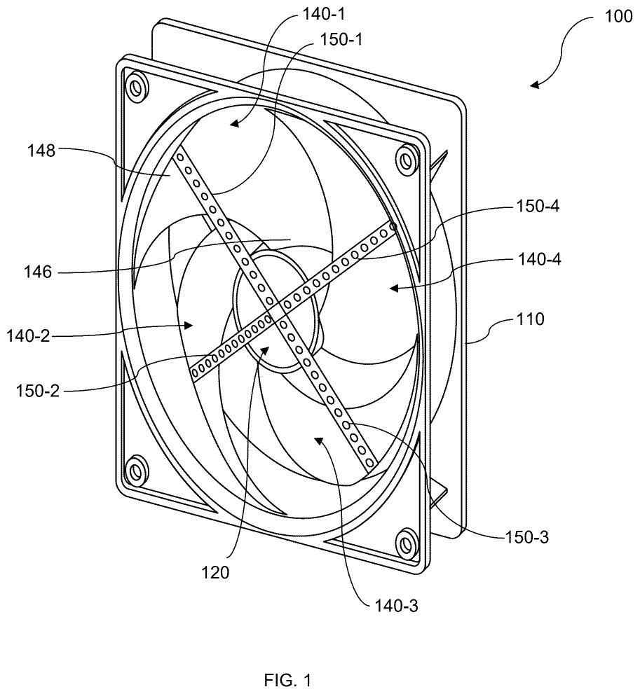

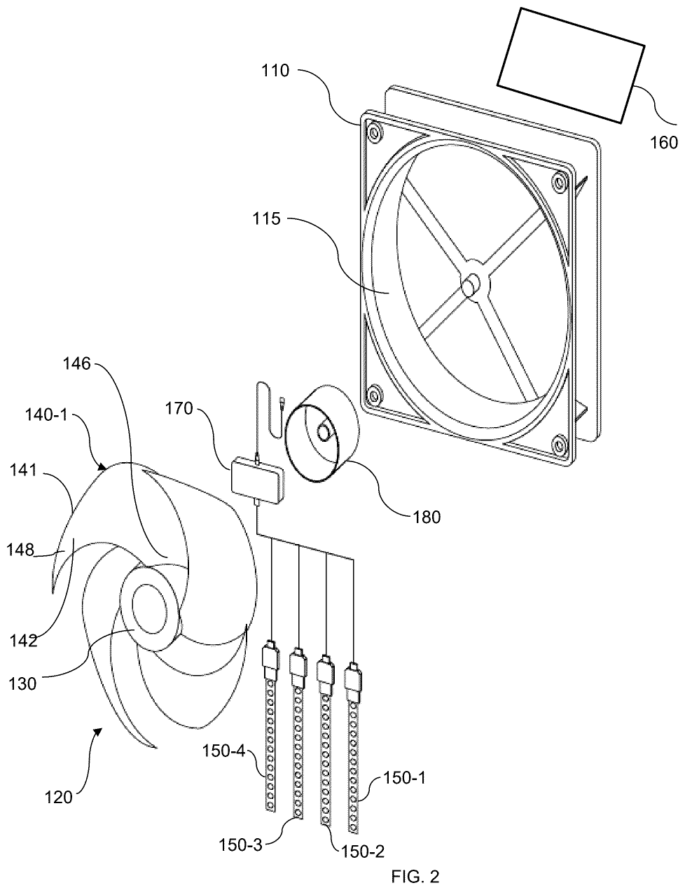

Reference is made to FIG. 1-2 which show an illustrative system 100 for displaying multimedia content on a computer cooling fan, according to an embodiment. FIG. 1 shows an assembled view of an embodiment of the system 100 while FIG. 2 shows a disassembled view of the components of the system 100. The system 100 consists of at least a frame 110 having a central cavity 115, a computer cooling fan 120, and at least display one strip 150, e.g., one of the display strips 150-1 through 150-4, where a single one may be referred to herein individually as a display strip 150 and where more than one may be referred to as display strips 150.

In an embodiment, the frame 110 is adapted to fit into a personal computer (PC), a laptop, and the like. The computer cooling fan 120 is positioned within the central cavity 115 of the frame 110. The computer cooling fan 120 consists of at least a hub 130 and a plurality of fan blades 140, e.g., the fan blade 140-1 through 140-4. It should be noted that the computer cooling fan 120 may be positioned in proximity to the central processing unit (CPU) of a PC, graphics card, etc., for cooling down such electronic components.

A stator 180 is positioned in the middle of the central cavity 115. The stator 180 is designed to receive the hub 130 such that the hub 130 rotates about the stator 180 and within the central cavity 115. It should be noted that the computer cooling fan 120 is driven by an electric motor (not shown).

According to one embodiment, each fan blade of the plurality of fan blades 140 has a back surface 141 and a front surface 142. The back surface 141 is directed generally toward the central cavity 115 and the front surface 142 being opposite to the back surface 141. In addition, each fan blade 140 of the plurality of fan blades 140 has a first end 146 and a second end 148. The first end 146 is attached to the hub 130 and the second end 148 is opposite to the first end 146. Generally, the second end of the fan blade is that part of the fan blade that is distal from the hub and may be located in proximity to the portion of the frame that defines the central cavity. The central cavity 115 is adapted to receive the computer cooling fan 120 such that the plurality of fan blades 140 is adapted to rotate within the central cavity 115 and cool the components of the electronic device, e.g., PC, in which the system is installed.

In an embodiment, at least one display strip 150 is mounted so as to extend from hub 130 to a point on the front surface 142 of at least one fan blade 140. For example, as shown in FIG. 1, each display strip 150 may extend from the center of the hub 130 (FIG. 2) and up to the second end 148 of the fan blade 140.

Each display strip 150 may be implemented as a strip containing one or more display elements, e.g., a strip containing LEDs, a strip containing one or more liquid crystal display (LCD) elements, one or more bulbs, the like, and combinations thereof. Also, in various embodiments, the individual display elements of any one of display strips 150 need not be linearly arranged and, furthermore, there may be gaps between the various display elements that make up a display strip. In an embodiment, the display elements of a display strip 150 are arranged, at least in part, in a two-dimensional array. When multiple display strips 150 are employed in an embodiment, there is no need that that any of the display strips 150 employed be identical. According to another embodiment, a display strip may 150 be mounted to at least one of: the back surface, the front surface, both surfaces of a fan blade 140.

In an embodiment, the system 100 further includes a display management module (DMM) 160 (FIG. 2). The DMM 160 is configured to receive real-time processing data and multimedia content data from hardware, e.g., a PC, a laptop computer, one or more sensors, etc., software, e.g., an operating system, an application, etc., a combination thereof, and the like.

Real-time processing data refers to information regarding the processing load of the computing device, e.g., central processing unit (CPU) load, in which the system 100 is installed. The real-time processing data continuously indicates the revolutions per minute (RPM) that is required to be achieved by the computer cooling fan 120 to obtain proper, and preferably optimal, performance of the computing device, e.g., a PC, and prevent overheating thereof. The real-time processing data may contain a target RPM to be achieved or may be information from which DMM 160 can determine the target RPM.

The multimedia content data refers to images, videos, textual, a combination thereof and the like. The multimedia content data may be transmitted to the DMM 160 by an electronic device, e.g., a PC, in which the system 100 is installed and operates. It should be noted that the multimedia content data may be transmitted to the DMM 160 by a PC, laptop, smartphone, wearable device, computer software, mobile application, and the like.

In an embodiment, the DMM 160 generates a display strip's operation schedule for displaying the multimedia content via the display strips 150. The display strip's operation schedule is generated based on the number of display strips 150 installed in system 100, the number of display elements, e.g., bulbs, LEDs, LCDs, etc., in each display strip 150, the arrangement of the lighting units on the display strips, the real-time processing data, and the multimedia content data. The display strip's operation schedule determines how the elements of display strips 150 would be operated, e.g., illuminated, to display the multimedia content by taking into account, i.e., based on, the rotation of the fan blades on which at least one display strip 150 is mounted. By leveraging the persistence of vision (POV) effect, the rapidly moving display strips 150 under control of DMM 160 can create the illusion of continuous imagery, seamlessly blending frames into a coherent multimedia display.

In an embodiment, the system 100 further includes at least one display controller 170. The display controller 170 controls the operation of, for example, each LED of the display strip 150, based on the display strip's operation schedule which is supplied, e.g., periodically or continuously, e.g., in real-time, from the DMM 160 to the display controller 170.

Each display strip 150 is connected to and powered by a display controller 170. The display controller 170 is connected to the DMM and adapted to receive inputs, such as the display strips' display strip's operation schedule, from the DMM 160. In an embodiment, each of computer cooling fans 120 includes its own respective display controller 170. In another embodiment, a display controller may be shared amongst two or more computer cooling fans 120.

It should be noted that a single DMM, e.g., the DMM 160, may be configured to control more than one computer cooling fan 120, each of which may include one or more display strips 150. For example, a PC may include eight computer cooling fans 120 and the DMM 160 may be used to control several, or even all, of them. According to the same example, a single DMM 160 may be connected to eight display controllers 170, where each display controller 170 is connected to the display strips of each respective one of eight computer cooling fans 120.

According to another embodiment, a single display controller 170 that is connected to a DMM 160 may be connected to all of the computer cooling fans of the electronic device, e.g., PC, and also configured to control the display strips 150 of all of the computer cooling fans 120. In such an embodiment, when there are eight computer cooling fans 120 in the electronic device, there may be only a single DMM 160 and single display controller 170 where the single display controller 170 is connected to and controls the display strips of each respective one of eight computer cooling fans 120

The DMM 160 may be configured to cause multiple computer cooling fans, e.g., the computer cooling fan 120, to operate as a single display by controlling all of the display strips 150 of all of the computer cooling fans 120. For example, five computer cooling fans are used as a single display to display an image, where each computer cooling fan, having at least one display strip, is utilized for displaying a portion of the image, which together forms the entire image. Alternatively, the DMM 160 may display different multimedia content on each computer cooling fan 120. For example, one computer cooling fan may display the date and time, while the second computer cooling fan displays a video related to a game the user is playing.

According to one embodiment, the DMM 160 receives real-time processing data from the PC in which the system 100 is installed and operates. This is because the computer cooling fan 120 serves two purposes: 1) cooling the PC and 2) displaying multimedia content via the computer cooling fan 120. As such, the DMM 160 must adjust the display strip's operation schedule based on the real-time processing data received from the PC so that the multimedia content is properly displayed based on whatever speed the computer cooling fan 120 is rotating regardless of how that rotation speed is set.

In one embodiment, the DMM 160 does not itself control the speed of the computer cooling fan 120. Rather, according to this embodiment, the speed of the computer cooling fan 120 may be set and controlled elsewhere, e.g., by the central processing unit (CPU) of the PC. Nevertheless, DMM 160 adjusts the display strip's operation schedule based on the real-time processing data, which may include an explicit indication of the rotation speed, so that the multimedia content is properly displayed based on the speed at which the computer cooling fan 120 is rotating.

According to yet another embodiment, the DMM 160 itself is adapted to control the rotation speed of the computer cooling fan 120, e.g., based on the real-time processing data. Furthermore, DMM 160 adjusts the display strip's operation schedule based on the rotation speed it sets so that the multimedia content is properly displayed.

Note that if the DMM 160 did not adjust the display strip's operation schedule based on the rotation speed, regardless of how the rotation speed is determined, the multimedia content would not be properly displayed. Thus, in accordance with the principles of the disclosure, the display strip's operation schedule of computer cooling fan 120 is dynamically adjusted by DMM 160 based on the computing device's real-time processing data, which is reflective of the computing device's thermal load, so that system 100 continuously synchronizes the multimedia display with whatever rotational speed is required of or set for cooling fan 120 to obtain proper operation of the computing device. Advantageously, a proper multimedia display is maintained regardless of the cooling function required of cooling fan 120.

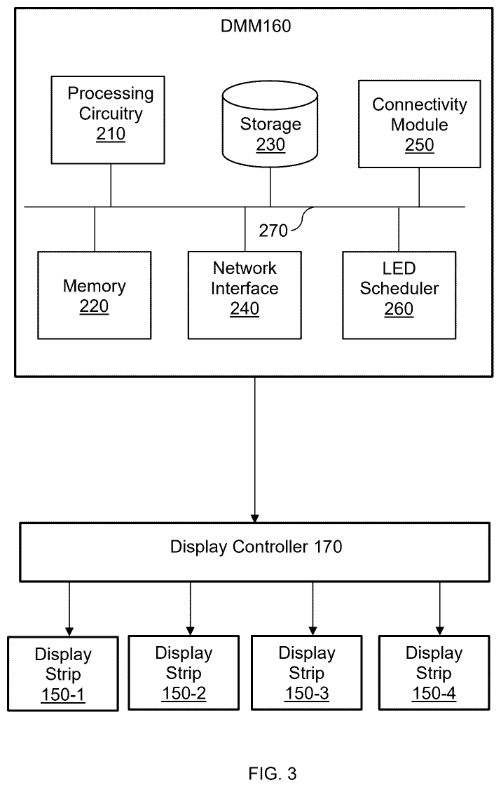

Reference is now made to FIG. 3 which shows an illustrative structure for the DMM 160 and the display controller 170, according to an embodiment. The DMM 160 includes a processing circuitry 210 coupled to a memory 220, a storage 230, a network interface 240, a connectivity module 250, and LED scheduler 260. In an embodiment, the components of the DMM 160 may be communicatively connected via a bus 270.

The processing circuitry 210 may be realized as one or more hardware logic components and circuits. For example, and without limitation, illustrative types of hardware logic components that can be used include field programmable gate arrays (FPGAs), application-specific integrated circuits (ASICs), Application-specific standard products (ASSPs), system-on-a-chip systems (SOCs), GPUs, general-purpose microprocessors, microcontrollers, digital signal processors (DSPs), and the like, or any other hardware logic components that can perform calculations or other manipulations of information.

The memory 220 may be volatile, e.g., RAM, etc., non-volatile, e.g., ROM, flash memory, etc., or a combination thereof. In one configuration, computer readable instructions to implement one or more embodiments disclosed herein may be stored in the storage 230.

In another embodiment, the memory 220 is configured to store software. Software shall be construed broadly to mean any type of instructions, whether referred to as software, firmware, middleware, microcode, hardware description language, or otherwise. Instructions may include code, e.g., in source code format, binary code format, executable code format, or any other suitable format of code. The instructions, when executed by the processing circuitry 210, cause the processing circuitry 210 to perform the various processes described herein.

The storage 230 may be magnetic storage, optical storage, and the like, and may be realized, for example, as flash memory or any other medium which can be used to store the desired information.

The network interface 240 allows the DMM 160 to communicate with one or more web sources, electronic devices that are connected to the web, and the like. For example, the network interface 240 allows the DMM 160 to receive multimedia content data from web sources, user devices, and the like. In addition, the network interface 240 allows the DMM 160 to send data, notifications, etc. to one or more user devices. The DMM 160 may further include an input/output (I/O) interface (not shown) allowing the DMM 160 to communicate with, for example, the PC in which the system 100 operates, the display controller 170, and the like.

The connectivity module 250 may include for example, wired or wireless communication, such as but not limited to, Bluetooth, Near Field Communication (NFC), and the like. The connectivity module 250 allowing the DMM 160 to receive multimedia content from different devices using, for example, Bluetooth technology.

The LED scheduler 260 may include a combination of hardware and software that are configured to determine the display strips' operation schedule based on the number of predetermined display strips 150, the number of LEDs in each display strip 150, the real-time processing data and the multimedia content data that is discussed in greater details in FIG. 1-2.

The display controller 170 may be implemented as a microcontroller, e.g., a microcontroller having a similar structure to DMM 160 but a) without network interface 240 and connectivity module 250, b) where the LED scheduler is used to implement a received display strips' operation schedule, and c) an input/output (I/O) interface (not shown) allowing the display controller 170 to communicate with, for example, DMM 160 and the display strips 150. The display controller 170 receives the display strips' operation schedule, generated by the DMM 160, and processes the display strips' operation schedule to generate control signals for the one or more display strips 150, e.g., the display strips 150-1 through 150-4.

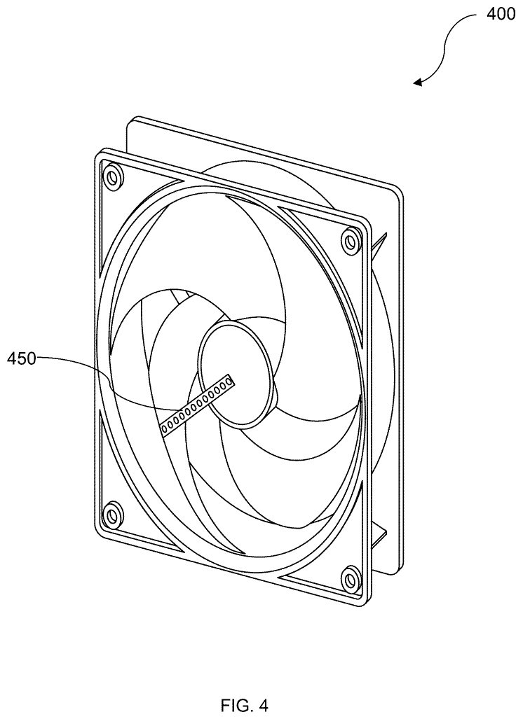

Reference is now made to FIG. 4 which shows an isometric view of an illustrative system 400, according to an embodiment. Although the system 400 includes four computer cooling fan blades as the system 100 of FIGS. 1-2 included, the system 400 includes only one display strip 450 and it still can operate and display multimedia content using the computer cooling fan blades. Note that display strip 450 is placed so that it extends from the center of the hub toward a point on the second end of the fan blade, which may be at or adjacent to the second end, and may be on the front surface and/or the back surface of the fan blade.

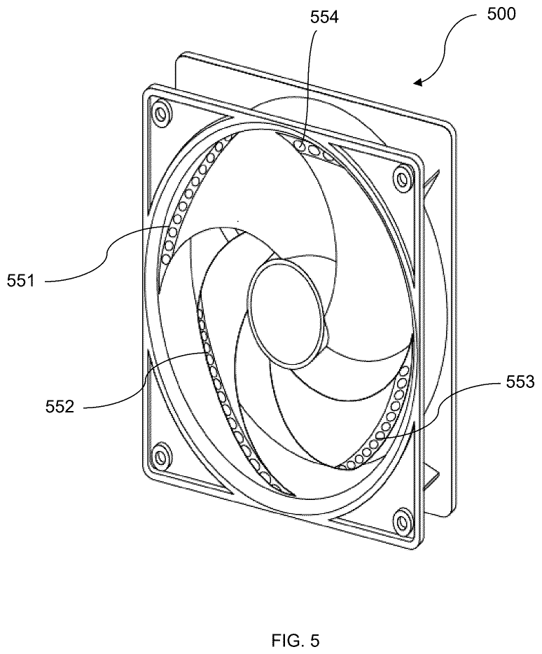

FIG. 5 shows an embodiment 500 of an illustrative system for displaying multimedia content on a computer cooling fan in which the display strips 551 through 554, are mounted on the front surface of the fan blades adjacent to and directionally along the second end.

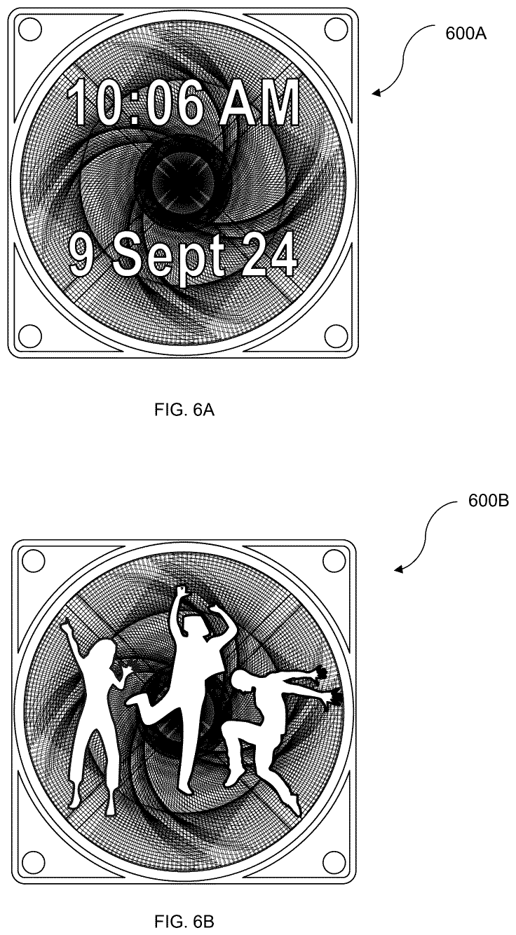

FIGS. 6A and 6B show a front view of an illustrative system for displaying multimedia content on a computer cooling fan, while multimedia content is displayed, according to an embodiment. The multimedia content 600A presents the time and date. It should be noted that the time and date, and any other multimedia content, may be presented as a static image, dynamic video, and the like. The multimedia content 600B presents a video of a dancing human being.

It should be noted that the multimedia content presented using the system 100 may be seen through, for example, a fan guard or a grill. Also, in many cases the computer cases are transparent so that the multimedia can be seen through the transparent computer case, even when the display strips are mounted to the back surface of the fan blades.

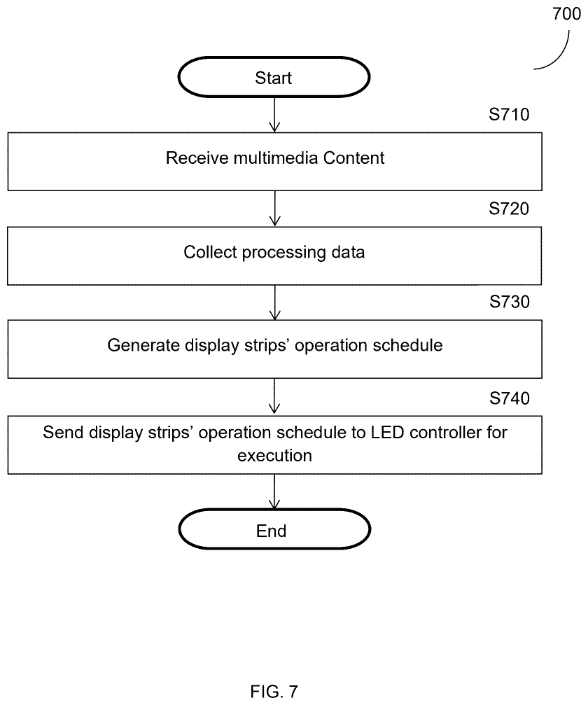

FIG. 7 is a flowchart of an illustrative method 700 for displaying multimedia content on computer cooling fans, according to an embodiment. According to one embodiment, the method 700 may be executed using a display management module, e.g., the DMM 160 of FIG. 3.

At S710, a multimedia content is received from an electronic device, e.g., a PC, a laptop, a mobile device, and the like. The multimedia content may include an image, a logo, a video, a text, and so on.

At S720, processing data is collected in real-time, or near real-time, from the electronic device on which the system, e.g., the system 100 of FIG. 1-2, operates. The processing data refers to the processing load of the computing device, e.g., central processing unit (CPU) load, in which the system operates. The real-time processing data continuously indicates the computer cooling fan 120 revolutions per minute (RPM) that is required to maintain the optimal performances of the computing device (e.g., PC) and prevent overheating.

At S730, a display strips' operation schedule is generated. The display strips' operation schedule determines how the display strips, e.g., the display strips 150 of FIG. 1-2, function to display the multimedia content, while utilizing the rotation of the fan blades, as further discussed hereinabove.

At S740, the display strips' operation schedule is sent to a display controller, e.g., the display controller 170 of FIG. 2-3. Thus, the display controller 170 controls the display strips 150 so that the multimedia is presented on the computer cooling fan, e.g. the computer cooling fan 120 of FIG. 1-2.

The disclosure presents several key advantages. First and foremost, the integration of display strips onto the fan blades allows the cooling fan to serve a dual purpose: both 1) cooling the computer and 2) displaying multimedia content. This not only enhances the visual appearance of a PC, especially in cases where components are visible through transparent casings or grills, but also utilizes otherwise idle space in a creative and practical way.

Another significant advantage lies in the real-time adaptability of the system. The DMM receives real-time data about the computer's processing load and adjusts the operation of the LEDs with respect to the processing load so as to allow for seamless multimedia displays even during high CPU usage. This guarantees that the cooling function remains unaffected by the multimedia display and thus offers a seamless and efficient solution for users.

It is important to note that the embodiments disclosed herein are only examples of the many advantageous uses of the innovative teachings herein. In general, statements made in the specification of the present application do not necessarily limit any of the various claimed embodiments. Moreover, some statements may apply to some inventive features but not to others. In general, unless otherwise indicated, singular elements may be in plural and vice versa with no loss of generality. In the drawings, like numerals refer to like parts through several views.

All examples and conditional language recited herein are intended for pedagogical purposes to aid the reader in understanding the principles of the disclosed embodiment and the concepts contributed by the inventor to furthering the art and are to be construed as being without limitation to such specifically recited examples and conditions. Moreover, all statements herein reciting principles, aspects, and embodiments of the disclosed embodiments, as well as specific examples thereof, are intended to encompass both structural and functional equivalents thereof. Additionally, it is intended that such equivalents include both currently known equivalents as well as equivalents developed in the future, i.e., any elements developed that perform the same function, regardless of structure.

It should be understood that any reference to an element herein using a designation such as “first,” “second,” and so forth does not generally limit the quantity or order of those elements. Rather, these designations are generally used herein as a convenient method of distinguishing between two or more elements or instances of an element. Thus, a reference to first and second elements does not mean that only two elements may be employed there or that the first element must precede the second element in some manner. Also, unless stated otherwise, a set of elements comprises one or more elements.

As used herein, the phrase “at least one of” followed by a listing of items means that any of the listed items can be utilized individually, or any combination of two or more of the listed items can be utilized. For example, if a system is described as including “at least one of A, B, and C,” the system can include A alone; B alone; C alone; 2A; 2B; 2C; 3A; A and B in combination; B and C in combination; A and C in combination; A, B, and C in combination; 2A and C in combination; A, 3B, and 2C in combination; and the like.

What is claimed is:

1. A system for displaying multimedia content on a computer cooling fan, comprising:
a frame having a central cavity;
a computer cooling fan positioned within the central cavity, wherein the computer cooling fan includes at least a hub and a plurality of fan blades, wherein each fan blade of the plurality of fan blades has a back surface directed to the central cavity and a front surface being opposite to the back surface, wherein each fan blade of the plurality of fan blades has a first end that is attached to the hub and a second end being opposite to the first end, wherein the central cavity is adapted to receive the computer cooling fan such that the hub and the plurality of fan blades are adapted to rotate together within the central cavity;
at least one display strip mounted to at least one point of one of the front surface and the back surface of at least one of the plurality of fan blades, wherein the at least one display strip is arranged so as to rotate within the central cavity at the same rate as computer cooling fan rotates when the computer cooling fan is rotating; and
circuitry regulating what is displayed by the at least one display strip over time so that a multimedia content is perceived to be displayed by an observer of the system regardless of an instantaneous rotation speed of the computer cooling fan.

2. The system of claim 1, wherein the circuitry further comprises:
a display management module (DMM) configured to receive real-time processing data and multimedia content data.

3. The system of claim 2, wherein the DMM generates a display strips' operation schedule for controlling the at least one display strip so as to display of the multimedia content.

4. The system of claim 3, wherein the display strips' operation schedule is based how many display strips make up the at least one display strip and their respective mounting arrangement, a number of display elements in each display strip, the real-time processing data and the multimedia content data.

5. The system of claim 3, further comprises:
at least one display controller, wherein the at least one display controller is configured to operate each display element of the at least one display strip based on the display strips' operation schedule.

6. The system of claim 5, wherein each display strip is connected to and powered by the at least one display controller.

7. The system of claim 1, wherein the hub rotates about a stator that is positioned in the middle of the central cavity.

8. The system of claim 1, wherein the at least one display strip extends from the hub to the at least one point of one of the front surface and the back surface of at least one of the plurality of fan blades.

9. The system of claim 8, wherein the at least one point of one of the front surface and the back surface of at least one of the plurality of fan blades is substantially adjacent to the second end of the at least one of the plurality of fan blades.

10. The system of claim 8, wherein the at least one point of one of the front surface and the back surface of at least one of the plurality of fan blades is a point on the at least one of the plurality of fan blades that is distal from the hub.

11. The system of claim 8, wherein the at least one display strip extends from the center of the hub.

12. The system of claim 1, wherein the at least one point of one of the front surface and the back surface of at least one of the plurality of fan blades is substantially adjacent to the second end of the at least one of the plurality of fan blades and the at least one display strip is mounted directionally along a portion of the second end of the at least one of the plurality of fan blades.

13. The system of claim 1, wherein the circuitry regulating what is displayed by the at least one display strip further controls the instantaneous rotation speed of the computer cooling fan.

14. The system of claim 1, wherein the instantaneous rotation speed of the computer cooling fan is controlled by circuitry other than the circuitry regulating what is displayed by the at least one display strip.

15. A method for displaying multimedia content on a computer cooling fan, the computer cooling fan comprising:
a frame having a central cavity;
a computer cooling fan positioned within the central cavity, wherein the computer cooling fan includes at least a hub and a plurality of fan blades, wherein each fan blade of the plurality of fan blades has a back surface directed to the central cavity and a front surface being opposite to the back surface, wherein each fan blade of the plurality of fan blades has a first end that is attached to the hub and a second end being opposite to the first end, wherein the central cavity is adapted to receive the computer cooling fan such that the hub and the plurality of fan blades are adapted to rotate together within the central cavity;
at least one display strip mounted to at least one point of one of the front surface and the back surface of at least one of the plurality of fan blades, wherein the at least one display strip is arranged so as to rotate within the central cavity at the same rate as computer cooling fan rotates when the computer cooling fan is rotating; and
circuitry regulating what is displayed by the at least one display strip over time so that a multimedia content is perceived to be displayed by an observer of the computer cooling fan regardless of an instantaneous rotation speed of the computer cooling fan;
the method comprising:
receiving the multimedia content;
obtaining real-time processing data;
generating a display strips' operation schedule for controlling the at least one display strip so as to display of the multimedia content; and
supplying the display strips' operation schedule to at least one display controller configured to operate each display element of the at least one display strip based on the display strips' operation schedule.
